(19) United States
(12) Patent Application Publication
(10) Pub. No.: US 2026/0182453 A1
(43) Pub. Date: Jun. 25, 2026

(54) PHOTON WAVELENGTH CONVERSION ELEMENTS

(71) Applicant: Sensors Unlimited, Inc., Princeton, NJ (US)

(72) Inventors: Richard J. Fustos, Bordentown, NJ (US); Krishna Linga, Plainsboro, NJ (US)

(21) Appl. No.: 18/988,630

(22) Filed: Dec. 19, 2024

(51) Int. Cl. H01L 25/16; H01L 23/522; H10F 30/225; H10F 39/00; H10F 77/124

(52) U.S. Cl. CPC H10W 90/00; H10F 30/225; H10F 39/8063; H10F 77/1248; H10W 20/42

(57) ABSTRACT

A photon wavelength converter includes a substrate. The photon wavelength converter also includes a photodetector layer stack disposed over the substrate and configured to receive radiation of a first wavelength and to convert the radiation of the first wavelength into one or more electrical signals. The photodetector layer stack includes a first photodetector layer and a second photodetector layer including indium gallium arsenide (InGaAs) or indium gallium arsenide phosphide (InGaAsP) disposed over the first photodetector layer. The photon wavelength converter further includes an array of light emitting elements monolithically integrated into the photodetector layer stack and configured to convert the one or more electrical signals into radiation of a second wavelength.

### TECHNICAL FIELD

This disclosure relates generally to light signal conversion devices and processes. More specifically, this disclosure relates to photon wavelength conversion elements.

### BACKGROUND

Short-wave infrared radiation imagers are devices that convert non-visible radiation to visible light and have been fabricated using silicon-based read-out integrated circuit (ROICs) or custom application-specific integrated circuits (ASICs) that interface to photodiode arrays formed using exotic semiconductors. An ROIC or ASIC may be used to integrate, digitize, and output a quantity of photons that hit the photodiode array. The ROIC itself draws a fair amount of power and has limits in terms of noise and dynamic range. In many applications, the digitized signal is processed using support circuitry, which itself consumes a large amount of power, and is sent out to a display to be turned into visible light for a user to observe. These systems are often complex, which increases manufacturing costs and device weights. Increased weight may be of particular concern in handheld or head-worn imagers, such as helmet-mounted imagers.

### SUMMARY

This disclosure provides photon wavelength conversion elements.

In some examples, a photon wavelength converter may include a substrate. The photon wavelength converter may also include a photodetector layer stack disposed over the substrate and configured to receive radiation of a first wavelength and to convert the radiation of the first wavelength into one or more electrical signals. The photodetector layer stack may include a first photodetector layer and a second photodetector layer including indium gallium arsenide (InGaAs) or indium gallium arsenide phosphide (InGaAsP) disposed over the first photodetector layer. The photon wavelength converter may further include an array of light emitting elements monolithically integrated into the photodetector layer stack and configured to convert the one or more electrical signals into radiation of a second wavelength.

Any single one or any combination of the following features may be used with these examples. The photodetector layer stack may include diffusion vias embedded in a third photodetector layer disposed over the second photodetector layer. The photodetector layers may include an avalanche gain region to receive one or more electrical signals. The diffusion vias may couple the second photodetector layer to the array of light emitting elements. The array of light emitting elements may include a diode array having a plurality of radiation emitting diodes configured to receive the one or more electrical signals and convert the one or more electrical signals into the radiation of the second wavelength. The first wavelength may be outside a visible light range. The photon wavelength converter may further include a set of avalanche layers configured to amplify the radiation of the second wavelength. The photon wavelength converter may include a focusing lens configured to focus the radiation of the first wavelength onto the photodetector layer stack.

In other examples, an optical system may include a photon wavelength converter that includes a substrate, a photodetector layer stack, and an array of light emitting elements. The photodetector layer stack may be disposed over the substrate and be configured to receive radiation of a first wavelength and to convert the radiation of the first wavelength into one or more electrical signals. The photodetector layer stack may include a first photodetector layer and a second photodetector layer including InGaAs or InGaAsP disposed over the first photodetector layer. The photodetector layers may include an avalanche gain region to receive one or more electrical signals. The array of light emitting elements may be monolithically integrated into the photodetector layer stack and configured to convert the one or more electrical signals into radiation of a second wavelength. The optical system may also include a focusing lens disposed in front of the photon wavelength converter and configured to focus the radiation of the first wavelength onto the photon wavelength converter.

Any single one or any combination of the following features may be used with these examples. The photodetector layer stack may include diffusion vias embedded in a third photodetector layer disposed over the second photodetector layer. The diffusion vias may couple the second photodetector layer to the array of light emitting elements. The photodetector layers may include an avalanche gain region to receive one or more electrical signals. The array of light emitting elements may include a diode array having a plurality of radiation emitting diodes configured to receive the one or more electrical signals and convert the one or more electrical signals into the radiation of the second wavelength. The photon wavelength converter may further include a set of avalanche layers configured to amplify the radiation of the second wavelength. The first wavelength may be one of short-wave infrared, infrared, long-wave infrared, ultraviolet, or X-ray. The photon wavelength converter may include an oxide layer and a dielectric layer disposed over the photodetector layer stack, and the array of light emitting elements may be embedded in the dielectric layer.

In still other examples, a method may include receiving radiation of a first wavelength at a photon wavelength converter and converting the radiation into one or more electrical signals. The photon wavelength converter may include (i) a substrate, (ii) a photodetector layer stack disposed over the substrate and configured to receive the radiation of the first wavelength and to convert the radiation of the first wavelength into the one or more electrical signals, and (iii) an array of light emitting elements. The photodetector layer stack may include a first photodetector layer and a second photodetector layer including InGaAs or InGaAsP disposed over the first photodetector layer. The photodetector layers may include an avalanche gain region to receive one or more electrical signals. The method may also include sending the one or more electrical signals to the array of light emitting elements monolithically integrated into the photodetector layer stack and emitting radiation of a second wavelength from the array of light emitting elements based on the one or more electrical signals.

Any single one or any combination of the following features may be used with these examples. Diffusion vias may be embedded in a third photodetector layer disposed over the second photodetector layer, and the diffusion vias may couple the second photodetector layer to the array of light emitting elements. The photodetector layers may include an avalanche gain region to receive one or more electrical signals. The array of light emitting elements may include a diode array having a plurality of radiation emitting diodes configured to receive the one or more electrical signals and convert the one or more electrical signals into the radiation of the second wavelength. The array of light emitting elements may be embedded in a dielectric layer disposed over an oxide layer above the second photodetector layer. The method may include amplifying the one or more electrical signals using an avalanche region including a first set of avalanche layers and a second set of avalanche layers.

Other technical features may be readily apparent to one skilled in the art from the following figures, descriptions, and claims.

### BRIEF DESCRIPTION OF THE DRAWINGS

For a more complete understanding of this disclosure, reference is made to the following description, taken in conjunction with the accompanying drawings, in which:

FIG. 1 illustrates an example photon wavelength converter in accordance with this disclosure;

FIGS. 2A and 2B illustrate example cross-sectional views of the photon wavelength converter in accordance with this disclosure;

FIGS. 3A through 3C illustrate example schematic circuit diagrams of the photon wavelength converter in accordance with this disclosure; and

FIG. 4 illustrates an example method for converting radiation in accordance with this disclosure.

### DETAILED DESCRIPTION

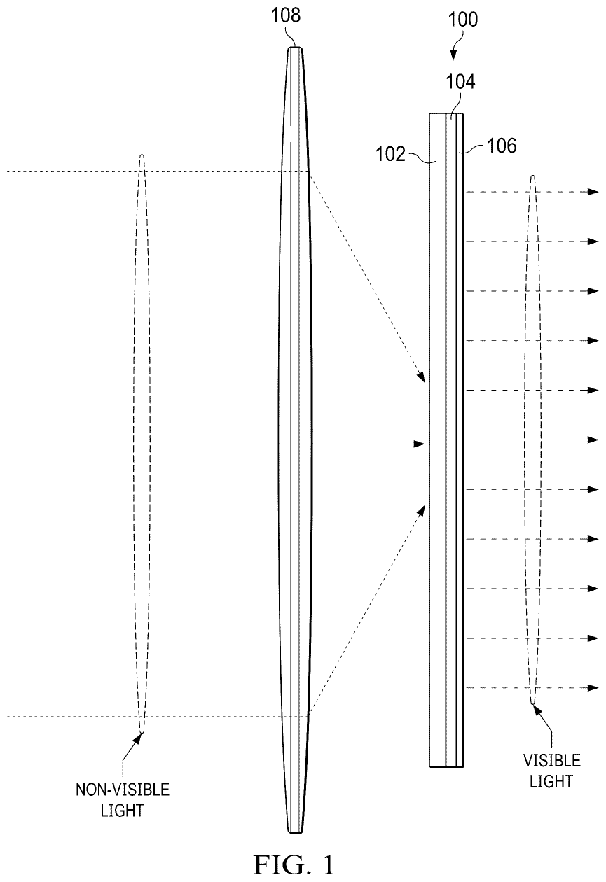

FIGS. 1 through 4, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As discussed above, short-wave infrared radiation imagers are devices that convert non-visible radiation to visible light and have been fabricated using silicon-based read-out integrated circuit (ROICs) or custom application-specific integrated circuits (ASICs) that interface to photodiode arrays formed using exotic semiconductors. A ROIC or ASIC may be used to integrate, digitize, and output a quantity of photons that hit the photodiode array. The ROIC itself draws a fair amount of power and has limits in terms of noise and dynamic range. In many applications, the digitized signal is processed using support circuitry, which itself consumes a large amount of power, and is sent out to a display to be turned into visible light for a user to observe. These systems are often complex, which increases manufacturing costs and device weights. Increased weight may be of particular concern in handheld or head-worn imagers, such as helmet-mounted imagers.

In particular, existing imagers have detect and display functionality using multiple substrates. For example, a substrate may include a photodetector layer disposed onto a substrate and be configured to receive radiation of a first wavelength, e.g., in the non-visible range, and to convert the radiation into electrical signals. Separately, another substrate may include light emitting elements that convert the electrical signals into radiation of a second wavelength, e.g., in the visible range. In these implementations, the photodetecting substrate and the radiating substrate are manufactured separately from one another, which requires a separate assembly process to combine the substrates. This results in high cost, reduced yield, and the need to employ high-cost assembly equipment. The present disclosure provides various photon wavelength conversion elements that may be used to convert radiation from one wavelength to another, such as from a non-visible wavelength to a visible wavelength. Each photon wavelength conversion element may include a photodetector layer stack that converts radiation of a first wavelength to one or more electrical signals. The one or more electrical signals may be provided to an array of light emitting elements that converts the one or more electrical signals into radiation of a second wavelength. The array of light emitting elements are monolithically integrated, e.g., embedded into, the photodetector layer stack that reduces the complexity of the device by eliminating the need for an ASIC to connect the array of light emitting elements to the photodetector. The present disclosure provides a method by which the manufacturing process may be greatly simplified and the end product is thinner and more robust. The photon detecting functionality and the light emitting functionality are combined into a single monolithic substrate that integrates the photodetector elements and the light emitting elements onto the same substrate. As a result, the photon wavelength conversion elements may be configured to convert, for instance, non-visible radiation into visible light without using an ROIC or ASIC. This may simplify processing, improve yield, and result in a more robust end product.

FIG. 1 illustrates an example photon wavelength converter 100 in accordance with this disclosure. As shown in FIG. 1, the photon wavelength converter 100 includes a substrate 102 and a photodetector layer stack 104 disposed over the substrate 102. The photodetector layer stack 104 is configured to receive radiation of a first wavelength (such as non-visible light as depicted) and to convert the radiation of the first wavelength into one or more electrical signals. The photodetector layer stack 104 may include any suitable wavelength-sensitive materials, such as indium phosphide (InP), indium gallium arsenide (InGaAs), and indium gallium arsenide phosphide (InGaAsP). In some embodiments, the photodetector layer stack 104 may be sensitive to short-wave infrared (SWIR), infrared (IR), long-wave infrared (LWIR), ultraviolet, or X-ray wavelengths.

Conversion of the radiation of the first wavelength to the one or more electrical signals may be direct or indirect. For example, a photodiode may convert radiation of the first wavelength directly to one or more electrical signals. However, in the case of a microbolometer or other device, incoming radiation may produce a change in a material, and the change may be detectable electrically to thereby create one or more electrical signals indirectly.

The photon wavelength converter 100 also includes an array of light emitting elements 106 monolithically integrated into or embedded in the photodetector layer stack 104. The monolithic integration of the array of light emitting elements 106 into the photodetector layer stack 104 allows for the photon detecting functionality and the light emitting functionality of the photon wavelength convertor 100 to be combined into a single substrate rather than relying on separate substrates combined together, e.g., using an ASIC. The array of light emitting elements 106 is configured to be electrically connected to the photodetector layer stack 104 to receive the one or more electrical signals from the photodetector layer stack 104. The array of light emitting elements 106 is also configured to convert the one or more electrical signals into radiation of a second wavelength (such as visible light as depicted). The array of light emitting elements 106 may emit the radiation of the second wavelength in any suitable direction(s).

In some embodiments, the array of light emitting elements 106 may represent a diode array having a plurality of radiation emitting diodes that receive the one or more electrical signals and convert the one or more electrical signals to the radiation of the second wavelength. For example, in some cases, the diode array forming the array of light emitting elements 106 may include the same number of radiation-emitting diodes as photodetectors. In this respect, each photodetector may be in isolated electrical communication with a corresponding radiation emitting diode.

Any suitable wavelengths may be received/converted by and output from the photon wavelength converter 100. In some embodiments, the first wavelength may be a non-visible wavelength, such as radiation outside of the visible spectrum or range. For example, the first wavelength may be included in the SWIR, IR, LWIR, ultraviolet, or X-ray band. Also, in some embodiments, the second wavelength may be in the visible spectrum or range. For instance, the array of light emitting elements 106 may be formed using light emitting diodes (LEDs), such as organic LEDs.

In some embodiments, a translucent conductive layer (not shown) may be disposed over the array of light emitting elements 106 and may be configured to pass radiation of the second wavelength therethrough. Thus, the translucent conductive layer may help to provide some level of protection for the array of light emitting elements 106. Additionally, a focusing lens 108 may be disposed in front of the substrate 102, such as when positioned so that the incoming radiation of the first wavelength passes through the focusing lens 108 prior to entering the substrate 102. The focusing lens 108 may be configured to focus the incoming radiation onto the substrate 102.

Although FIG. 1 illustrates one example of a photon wavelength converter 100, various changes may be made to FIG. 1. For example, various components in FIG. 1 may be combined, further subdivided, replicated, omitted, or rearranged and additional components may be added according to particular needs. Also, the photon wavelength converter 100 may be used in any suitable applications and can be incorporated into any larger systems as needed or desired. In some embodiments, for instance, the photon wavelength converter 100 may represent a low-cost direct replacement for handheld imagers or head-mounted displays, such as those that are used by firefighters, pilots, law enforcement personnel, or hobbyists.

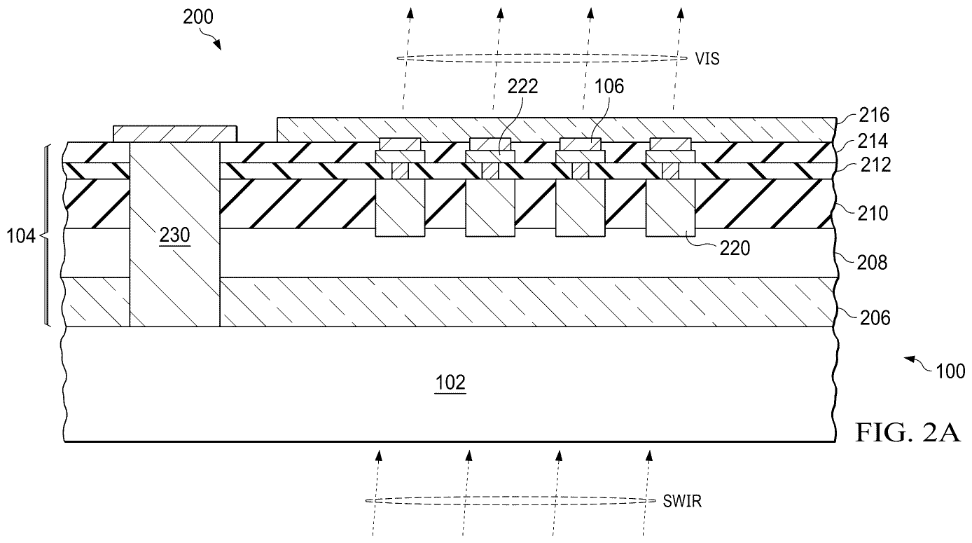

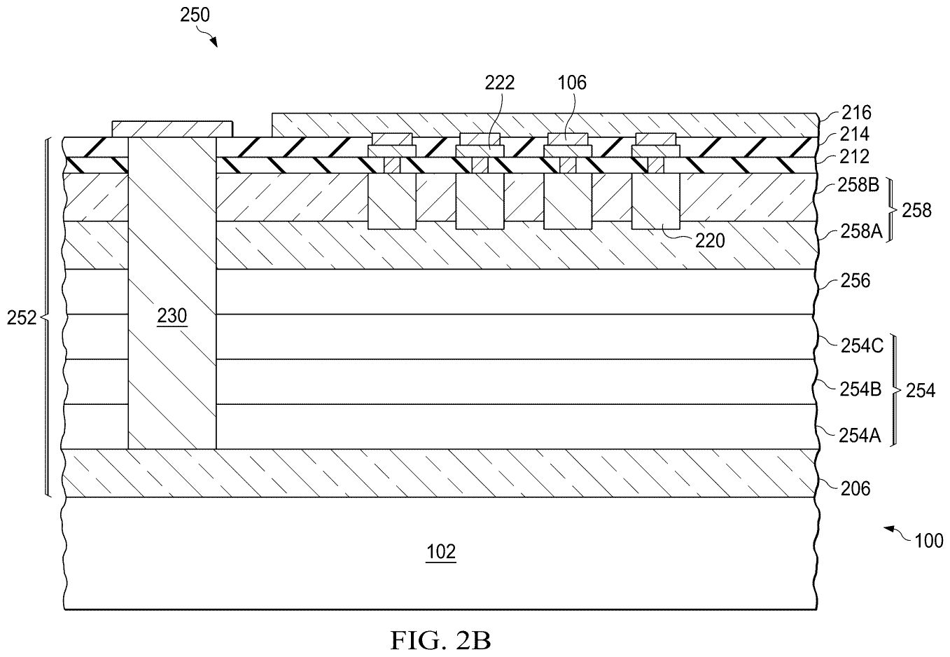

FIGS. 2A and 2B illustrate example cross-sectional views 200, 250 of the photon wavelength converter 100 in accordance with this disclosure. As shown in FIG. 2A, the illustrated embodiment of the photon wavelength converter 100 includes the substrate 102 with the photodetector layer stack 104 disposed thereon. The photodetector layer stack 104 in this example includes a first photodetector layer 206 disposed over the substrate 102, a second photodetector layer 208 disposed over the first photodetector layer 206, and an optional third photodetector layer 210 disposed over the second photodetector layer 208. Each photodetector layer 206-210 may include any suitable material(s). In some embodiments, the first photodetector layer 206 may include InP, the second photodetector layer 208 may include InGaAs or InGaAsP depending on the desired wavelength sensitivity, and the third photodetector layer 210 may include InP.

The first photodetector layer 206 may filter radiation received by the substrate 102 by a desired wavelength. For example, the first photodetector layer 206 may be configured to pass a wavelength range of about 1.0 μm to about 1.7 μm, which is the wavelength range for short-wave infrared radiation. The second photodetector layer 208 may convert electromagnetic radiation into one or more electrical currents, such as to convert the short-wave infrared radiation or other radiation into one or more electrical currents. Thus, the second photodetector layer 208 can convert photons received through the substrate 102 into electrical current(s), such as by using the photoelectric effect.

The photon wavelength converter 100 may also include an oxide layer 212 disposed over the photodetector layer stack 104, a dielectric layer 214 disposed over the oxide layer 212, and a translucent conductive layer 216 disposed over the photodetector layer stack 104 (such as on the dielectric layer 214). The array of array of light emitting elements 106 is also monolithically integrated into the photodetector layer stack 104 and, in particular, the third photodetector layer 210. The integration or embedding of the array of light emitting elements 106 into the third photodetector layer 210, made of InP, allows for conversion of the received short wave infrared radiation that passes through the photodetector layer stack 104 to be converted into electrical energy to power the array of light emitting elements 106 which then radiates visible light.

In some embodiments, the array of light emitting elements 106 may be electrically coupled to an array of diffusion elements 220 embedded in the third photodetector layer 210 by diffusion vias 222. For example, the diffusion vias 222 may extend through the dielectric layer 214 and the oxide layer 212. The diffusion elements 220 may be embedded in the third photodetector layer 210 and be in direct contact with the diffusion vias 222 coupled to the array of light emitting elements 106. Each of the diffusion elements 220 can also extend into the second photodetector layer 208. In addition, the photon wavelength converter 100 may include at least one via 230 that provides an electrical connection to the substrate 102, such as when the at least one via 230 extends through the photodetector layer stack 104 to the substrate 102.

The monolithic integration of the array of light emitting elements 106 into the photodetector layer stack 104, such as in the third photodetector layer 210, and, optionally, into the oxide layer 212 and the dielectric layer 214, may be formed using deposition techniques, such as organic vapor deposition (OVPD), or simply spinning (spin coating or printing) a light emitting element material by dissolving it in a solvent to create a solution or using thermal evaporation. For example, the array of light emitting elements 106 may be monolithically integrated using a lithography deposition method, such as atomic layer deposition (ALD), on top of a masked photoresist and removing the photoresist after the deposition. Once the array of light emitting elements 106 material is either deposited or spun, the at least one via 230 will be made using a metal material, such as transparent indium tin oxide (ITO) or other suitable metals. Different arrays of light emitting elements 106 materials may require different deposition methods, e.g., physical vapor deposition or chemical vapor deposition, and any of the aforementioned deposition methods may be used, depending on the material chosen.

As shown in FIG. 2B, another illustrated embodiment of the photon wavelength converter 100 includes various elements that are the same as or similar to corresponding elements in FIG. 2A. For example, the photon wavelength converter 100 in FIG. 2B includes the oxide layer 212, the dielectric layer 214, and the translucent conductive layer 216 of the photodetector layer stack 104.

The photon wavelength converter 100 in FIG. 2B includes a photodetector layer stack 252 that is configured for avalanche internal gain and includes the first photodetector layer 206 disposed on the substrate 102. The photodetector layer stack 252 includes an avalanche gain region including a plurality of first set of avalanche layers 254, e.g., a first avalanche layer 254A, a second avalanche layer 254B, and a third avalanche layer 254C, disposed on the first photodetector layer 206. The first set of avalanche layers 254 may include InGaAsP layers. The avalanche gain region also includes a fourth avalanche layer 256 that may be disposed between the first set of avalanche layers 254 and a second set of avalanche layers 258, e.g., a fifth avalanche layer 258A and a sixth avalanche layer 258B. The fourth avalanche layer 256 may include InGaAs. The second set of avalanche layers 258 may include InP.

The iterative stacking of the first set of avalanche layers 254 followed by the iterative stacking of the second set of avalanche layers 258 amplifies the gain of the received infrared radiation at the substrate 102 to produce stronger signals at the array of light emitting elements 106, producing improved visible light.

Although FIGS. 2A and 2B illustrate examples of cross-sectional views 200, 250 of the photon wavelength converter 100, various changes may be made to FIGS. 2A and 2B. For example, various components in each of FIGS. 2A and 2B may be combined, further subdivided, replicated, omitted, or rearranged and additional components may be added according to particular needs. As a particular example, the photon wavelength converter 100 in FIG. 2B may be expanded to include an additional avalanche layer stack to further increase gain.

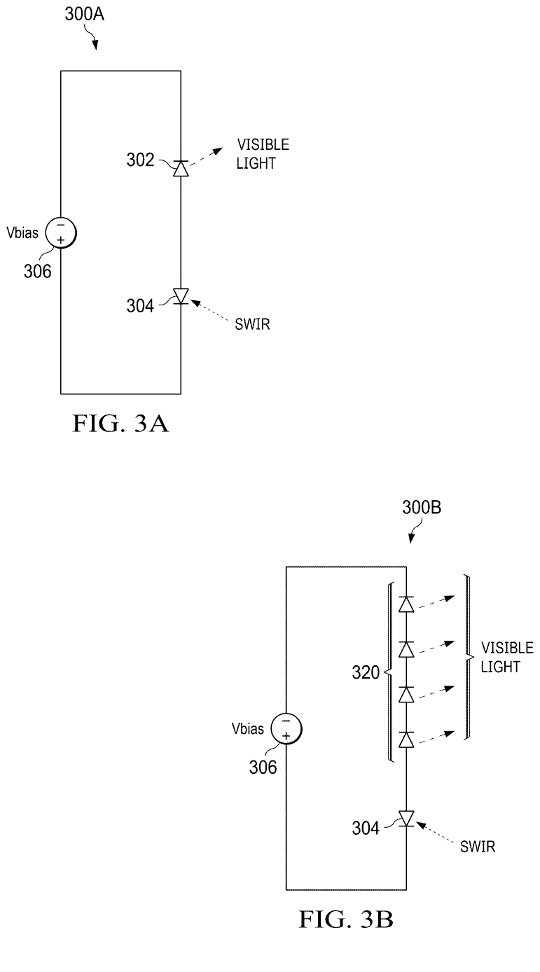

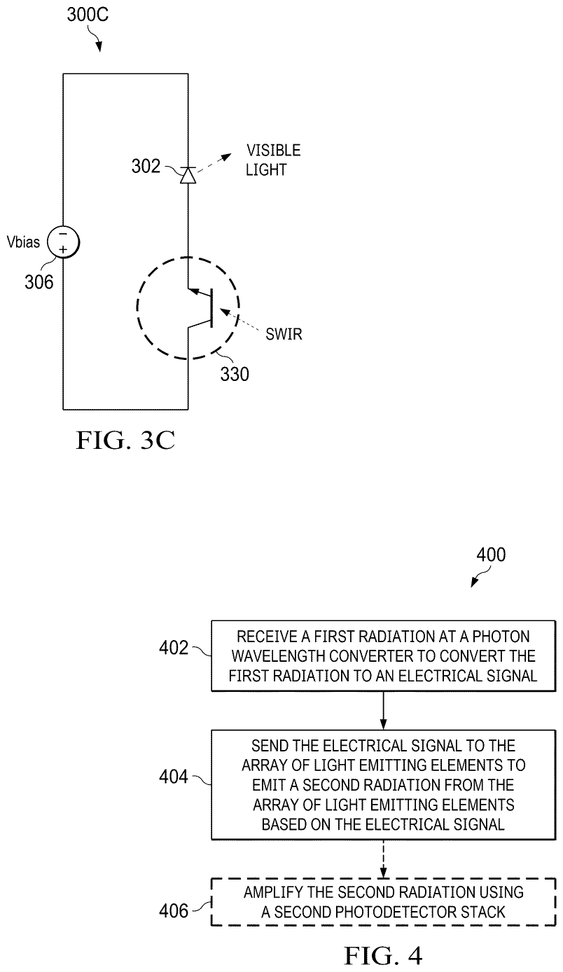

FIGS. 3A through 3C illustrate example schematic circuit diagrams 300A-300C of the photon wavelength converter 100 in accordance with this disclosure. As shown in FIG. 3A, the circuit diagram 300A includes a photodiode 302 coupled to a photodiode 304 and a voltage bias 306. The photodiode 302 may represent a visible light photodiode, and the photodiode 304 may represent an SWIR photodiode. The photodiode 302 can represent a forward-biased photodiode, and the photodiode 304 can represent a reverse-biased photodiode. The photodiode 304 may be representative of the substrate 102 and a bottom portion of the photodetector layer stack 104, such as the first photodetector layer 206 and the second photodetector layer 208 of the photon wavelength converter 100. The voltage bias 306 may be representative of an upper portion of the photodetector layer stack 104, such as the second photodetector layer 208 and the array of light emitting elements 106.

As shown in FIG. 3B, the circuit diagram 300B includes a chain of photodiodes 320 and the photodiode 304. The chain of photodiodes 320 can represent a chain of two or more visible light photodiodes. The chain of photodiodes 320 may be representative of embodiments of the photon wavelength converter 100 that include multiple photodetector layer stacks, such as when the photon wavelength converter 100 includes the photodetector layer stack 104 and the second photodetector layer stack 254 to provide additional gain from the same photocurrents.

As shown in FIG. 3C, the circuit diagram 300C includes the photodiode 302 and a phototransistor 330 (rather than a photodiode 304). The phototransistor 330 may represent an SWIR phototransistor. The phototransistor 330 may be configured to receive non-visible light radiation, such as short-wave infrared radiation, to allow for high controllable gain on the front end of the device. This approach may help to reduce or avoid the need to use multiple photodetector layer stacks.

Although FIGS. 3A through 3C illustrate examples of schematic circuit diagrams 300A-300C of the photon wavelength converter 100, various changes may be made to FIGS. 3A through 3C. For example, various components in each of FIGS. 3A through 3C may be combined, further subdivided, replicated, omitted, or rearranged and additional components may be added according to particular needs. As a particular example, the chain of photodiodes 320 from FIG. 3B may be used with the phototransistor 330 from FIG. 3C for additional gain.

FIG. 4 illustrates an example method 400 for converting radiation in accordance with this disclosure. For ease of explanation, the method 400 of FIG. 4 is described as being performed using the photon wavelength converter 100 of FIG. 1. However, the method 400 may be used with any other suitable system and any other suitable photon wavelength converter, such as any embodiment of the photon wavelength converter 100 described above.

As shown in FIG. 4, at step 402, the method 400 includes receiving first radiation (such as radiation having a first wavelength) at a photon wavelength converter for conversion to one or more electrical signals. For example, the substrate 102 of the photon wavelength converter 100 may receive non-visible radiation or other first radiation and transfer the first radiation to the photodetector layer stack 104, which converts the first radiation to one or more electrical signals. As a particular example, the first radiation may enter the second photodetector layer 208, where the photons from the radiation are converted into electrons to produce at least one electrical current.

At step 404, the one or more electrical signals are sent to an array of light emitting elements for conversion into radiation at a second wavelength. For example, the one or more electrical currents generated in the second photodetector layer 208 may travel to the array of diffusion vias 222 embedded in the third photodetector layer 210 and coupled to the diffusion elements 220, which provide the electrical current(s) to the array of light emitting elements 106. The electrical current(s) can cause the array of light emitting elements 106 to emit radiation at the second wavelength outward, such as through the translucent conductive layer 216 and to a user.

At optional step 406, the radiation at the second wavelength may be amplified using an avalanche region, e.g., the first set of avalanche layers 254, the fourth avalanche layer 256, and the second set of avalanche layers 258 as described in reference to FIG. 2B. For example, the received radiation at the substrate 102 may pass through the first photodetector layer 206 before the gain of the radiation is increased through the first set of avalanche layers 254 before being converted into electricity in the second set of avalanche layers 258 and subsequent conversion to visible light using the light emitting elements coupled to the second set of avalanche layers 258. This configuration allows for more generated photons for the same photocurrent from the received radiation, such as radiation received at the substrate 102 in step 402.

Although FIG. 4 illustrates one example of a method 400 for converting radiation, various changes may be made to FIG. 4. For example, while shown as a series of steps, various steps in FIG. 4 may overlap, occur in parallel, occur in a different order, or occur any number of times (including zero times).

It may be advantageous to set forth definitions of certain words and phrases used throughout this patent document. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A photon wavelength converter comprising:
a substrate;
a photodetector layer stack disposed over the substrate and configured to receive radiation of a first wavelength and to convert the radiation of the first wavelength into one or more electrical signals, wherein the photodetector layer stack includes a first photodetector layer and a second photodetector layer including indium gallium arsenide (InGaAs) or indium gallium arsenide phosphide (InGaAsP) disposed over the first photodetector layer; and
an array of light emitting elements monolithically integrated into the photodetector layer stack and configured to convert the one or more electrical signals into radiation of a second wavelength.

2. The photon wavelength converter of claim 1, wherein the photodetector layer stack further comprises diffusion vias embedded in a third photodetector layer disposed over the second photodetector layer.

3. The photon wavelength converter of claim 2, wherein the diffusion vias couple the second photodetector layer to the array of light emitting elements.

4. The photon wavelength converter of claim 1, wherein the array of light emitting elements comprises a diode array having a plurality of radiation emitting diodes configured to receive the one or more electrical signals and convert the one or more electrical signals into the radiation of the second wavelength.

5. The photon wavelength converter of claim 1, wherein the first wavelength is outside a visible light range.

6. The photon wavelength converter of claim 1, further comprising a set of avalanche layers configured to amplify the radiation of the second wavelength.

7. The photon wavelength converter of claim 1, further comprising a focusing lens configured to focus the radiation of the first wavelength onto the photodetector layer stack.

8. An optical system comprising:
a photon wavelength converter comprising:
a substrate;
a photodetector layer stack disposed over the substrate and configured to receive radiation of a first wavelength and to convert the radiation of the first wavelength into one or more electrical signals, wherein the photodetector layer stack includes a first photodetector layer and a second photodetector layer including indium gallium arsenide (InGaAs) or indium gallium arsenide phosphide (InGaAsP) disposed over the first photodetector layer; and
an array of light emitting elements monolithically integrated into the photodetector layer stack and configured to convert the one or more electrical signals into radiation of a second wavelength; and
a focusing lens disposed in front of the photon wavelength converter and configured to focus the radiation of the first wavelength onto the photon wavelength converter.

9. The optical system of claim 8, wherein the photodetector layer stack further comprises diffusion vias embedded in a third photodetector layer disposed over the second photodetector layer.

10. The optical system of claim 9, wherein the diffusion vias couple the second photodetector layer to the array of light emitting elements.

11. The optical system of claim 8, wherein the array of light emitting elements comprises a diode array having a plurality of radiation emitting diodes configured to receive the one or more electrical signals and convert the one or more electrical signals into the radiation of the second wavelength.

12. The optical system of claim 8, wherein the photon wavelength converter further comprises a set of avalanche layers configured to amplify the radiation of the second wavelength.

13. The optical system of claim 8, wherein the first wavelength is one of short-wave infrared, infrared, long-wave infrared, ultraviolet, or X-ray.

14. The optical system of claim 8, wherein the photon wavelength converter further comprises an oxide layer and a dielectric layer disposed over the photodetector layer stack, the array of light emitting elements embedded in the dielectric layer.

15. A method comprising:
receiving radiation of a first wavelength at a photon wavelength converter;
converting the radiation into one or more electrical signals, the photon wavelength converter comprising (i) a substrate, (ii) a photodetector layer stack disposed over the substrate and configured to receive the radiation of the first wavelength and to convert the radiation of the first wavelength into the one or more electrical signals, and (iii) an array of light emitting elements, wherein the photodetector layer stack includes a first photodetector layer and a second photodetector layer including indium gallium arsenide (InGaAs) or indium gallium arsenide phosphide (InGaAsP) disposed over the first photodetector layer;
sending the one or more electrical signals to the array of light emitting elements monolithically integrated into the photodetector layer stack; and
emitting radiation of a second wavelength from the array of light emitting elements based on the one or more electrical signals.

16. The method of claim 15, wherein diffusion vias are embedded in a third photodetector layer disposed over the second photodetector layer.

17. The method of claim 16, wherein the diffusion vias couple the second photodetector layer to the array of light emitting elements.

18. The method of claim 15, wherein the array of light emitting elements comprises a diode array having a plurality of radiation emitting diodes configured to receive the one or more electrical signals and convert the one or more electrical signals into the radiation of the second wavelength.

19. The method of claim 15, wherein the array of light emitting elements is embedded in a dielectric layer disposed over an oxide layer.

20. The method of claim 15, further comprising:
amplifying the radiation of the second wavelength using an avalanche region including a first set of avalanche layers and a second set of avalanche layers.
